(19) United States
(12) Patent Application Publication
(10) Pub. No.: US 2024/0072035 A1
(43) Pub. Date: Feb. 29, 2024

(54) FLEXIBLE CELL BOUNDARY WITH CURVED GATE CUT REGION

(71) Applicant: INTERNATIONAL BUSINESS MACHINES CORPORATION, Armonk, NY (US)

(72) Inventors: Ruilong Xie, Niskayuna, NY (US); Indira Seshadri, Niskayuna, NY (US); Cheng Chi, Jersey City, NJ (US); Albert M. Chu, Nashua, NH (US)

(21) Appl. No.: 17/900,203

(22) Filed: Aug. 31, 2022

(51) Int. Cl. H01L 27/02; H01L 27/118

(52) U.S. Cl. CPC H01L 27/0207; H01L 27/11807; H01L 2027/11866

(57) ABSTRACT

A circuit is presented including a plurality of cells separated by a plurality of cell boundaries and at least one curved gate cut region disposed over a curved cell boundary of the plurality of cell boundaries. The at least one curved gate cut region separates a reduced active area from a widened active area. The reduced active area is defined above the curved cell boundary and the widened active area is defined below the curved cell boundary.

### BACKGROUND

The present invention relates generally to semiconductor devices, and more specifically, to a flexible cell boundary with a curved gate cut region.

As integrated circuits become smaller, layouts for the integrated circuits are changed to decrease the overall area occupied by an integrated circuit. Decreasing the area of the layout is accomplished by substituting new structures for integrated circuit elements that are smaller than previous versions of integrated circuit elements. Decreasing the area of the layout is also accomplished by reducing the distance between circuit elements in a layer of an integrated circuit. Smaller integrated circuits, and smaller integrated circuit elements, pose increasing difficulty in manufacturing processes because tolerances also become smaller. Thus, while electrical properties of some materials remain constant between generations of an integrated circuit, the manufacturing tolerances are increasingly difficult to satisfy because there is less room for error before an integrated circuit is negatively impacted by deviations from a manufacturing process flow.

### SUMMARY

In accordance with an embodiment, a circuit is provided. The circuit includes a plurality of cells separated by a plurality of cell boundaries and at least one curved gate cut region disposed over a curved cell boundary of the plurality of cell boundaries.

In accordance with another embodiment, a semiconductor device is provided. The semiconductor device includes a first circuit row including a first circuit portion having a first width and a second circuit portion having a second width, the first and second circuit portions being adjacent to each other and a second circuit row including a third circuit portion having a third width and a fourth circuit portion having a fourth width, the third and fourth circuit portions being adjacent to each other. The first width is larger than the second width and the fourth width is larger than the third width.

In accordance with yet another embodiment, a method for forming a semiconductor device is provided. The method includes separating a plurality of cells by a plurality of cell boundaries and constructing at least one curved gate cut region over a curved cell boundary of the plurality of cell boundaries.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a top view of an integrated circuit illustrating a curved cell boundary, in accordance with an embodiment of the present invention;

FIG. 2 is a cross-sectional view of the semiconductor structure of FIG. 1 where dummy gates are formed, in accordance with an embodiment of the present invention;

FIG. 3 is a cross-sectional view of the semiconductor structure of FIG. 2 where spacers and source/drain (S/D) epi regions are formed adjacent the dummy gates, in accordance with an embodiment of the present invention;

FIG. 4 is a cross-sectional view of the semiconductor structure of FIG. 3 where single diffusion breaks and double diffusion breaks are illustrated, in accordance with an embodiment of the present invention;

FIG. 5 is a cross-sectional view of the semiconductor structure of FIG. 4 where the dummy gates are removed and replaced with replacement metal gates (RMG), in accordance with an embodiment of the present invention;

FIG. 6 is a cross-sectional view of the semiconductor structure of FIG. 5 where gate cuts takes place, where at least one gate cut is curved, in accordance with an embodiment of the present invention;

FIG. 7 is a cross-sectional view of the semiconductor structure of FIG. 6 where contacts are formed to the S/D epi regions, in accordance with an embodiment of the present invention;

FIG. 8 is a cross-sectional view of the semiconductor structure of FIG. 7 where M1 metallization lines are formed and are mostly straight, in accordance with an embodiment of the present invention; and

FIG. 9 is a cross-sectional view of the semiconductor structure where M1 metallization lines are formed and some M1 lines are curved with the curved gate cut, in accordance with another embodiment of the present invention.

Throughout the drawings, same or similar reference numerals represent the same or similar elements.

### DETAILED DESCRIPTION

Embodiments in accordance with the present invention provide methods and devices for constructing a flexible cell boundary with a curved gate cut region.

To design an integrated circuit (IC) with some desired functionality, an IC designer uses electronic design automation (EDA) tools. These computer-based EDA tools enable the IC designer to efficiently design an electronic version of the IC, which describes in detail how a large number of semiconductor devices are to be arranged on a semiconductor substrate. These semiconductor devices, such as transistors, diodes, capacitors, resistors, and the like, can be arranged individually or in combination to form standard cells. Memory cells, logic circuits, amplifiers, inverters, and the like, are just a few examples of standard cells. Standard cells, possibly along with custom (e.g., non-standard cells) are tiled together to realize the functionality desired by the IC designer. The physical organization of the IC in this electronic design space is referred to as the layout. The IC layout includes a floor planning step that formalizes and refines the floorplan that was first conjured up during the architecture planning step. In this step, the entire die area is divided into physical partitions, and their shapes are molded while keeping in mind the area requirements, the flow of top level data and control buses, possibility of any future growth. Pins and ports are assigned a rough location, which can further be refined depending on the Place and Route results. During placement, all standard cells are placed in legal locations on site rows. The aim of this step is to minimize the wire length, while ensuring optimal placement that will help with faster timing convergence. The standard cells are divided by cell boundaries. In conventional systems, cell boundaries are straight. However, the exemplary embodiments of the present invention introduce curved or non-linear or non-straight cell boundaries. The curved gate cuts at the curved cell boundaries enable a larger active region next to a locally small active region to improve circuit performance.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

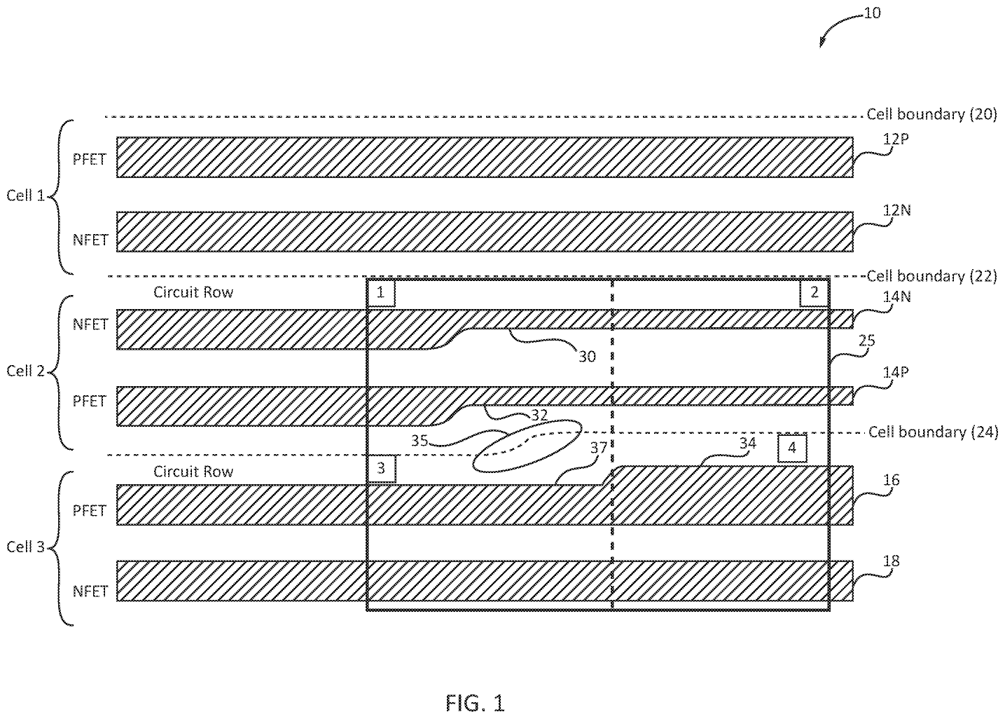

FIG. 1 is a top view of an integrated circuit illustrating a curved cell boundary, in accordance with an embodiment of the present invention.

In various example embodiments, a top view of an integrated circuit 10 includes a first cell boundary 20, a second cell boundary 22, and a third cell boundary 24. Cell boundary 20 is a straight line. Cell boundary 22 is a straight line. Cell boundary 24 is a curved line defining a curvature 35. Cell boundary 24 can be referred to as having a non-straight or non-linear portion or section. The non-straight or non-linear portion 35 can be curved or sloped or ramped.

Cell 1 includes a row of active regions of n-type field-effect-transistors (NFET) 12N and a row of active regions of p-type field-effect-transistors (PFET) 12P. Cell 2 includes rows of active regions of NFET 14N and a PFET 14P. The NFET 14N defines a tapered end 30 and the PFET 14P defines a tapered end 32. Cell 3 includes rows of active regions of PFET 16 and an NFET 18. The PFET 16 includes a tapered end 37. The tapered end 32 of the PFET 14P in Cell 2 and the tapered end 37 of the PFET 16 in Cell 3 are positioned adjacent the curvature 35 of cell boundary 24. As a result of the curvature 35, additional area 34 is saved, and devices with larger W_{eff} can be placed next to the device region with a smaller W_{eff} (e.g., 14P). The curvature 35 can be characterized as non-linear or sloped or slanted or ramped or oblique. It is noted that here the active region can represent all type of devices, such as planar devices, FINFETs, or nanosheet devices. If a FINFET is used, the active region can include different numbers of Fins, e.g., a wider active region can include 3 or 4 Fins, while smaller active regions can have 1 or 2 Fins.

Stated differently, a first circuit row (of Cell 2) includes a first circuit portion (1) having a first width and a second circuit portion (2) having a second width, the first and second circuit portions being adjacent to each other. The first and second circuit portions are horizontally aligned with respect to each other.

A second circuit row (of Cell 3) includes a third circuit portion (3) having a third width and a fourth circuit portion (4) having a fourth width, the third and fourth circuit portions being adjacent to each other. The third and fourth circuit portions are horizontally aligned with respect to each other. The first circuit portion (1) is vertically aligned with the third circuit portion (3), and the second circuit portion (2) is vertically aligned with the fourth circuit portion (4). The first, second, third, and fourth circuit portions can form a quadrant 25. Moreover, the first width is larger than the second width and the fourth width is larger than the third width. The difference in widths is the result of the curvature 35 of the curved cell boundary 24. Thus, a reduced active area is defined in the first circuit portion (1) and a widened or enlarged active area is defined in the third circuit portion (3). Similarly, a reduced active area is defined in the second circuit portion (2) and a widened or enlarged active area is defined in the fourth circuit portion (4).

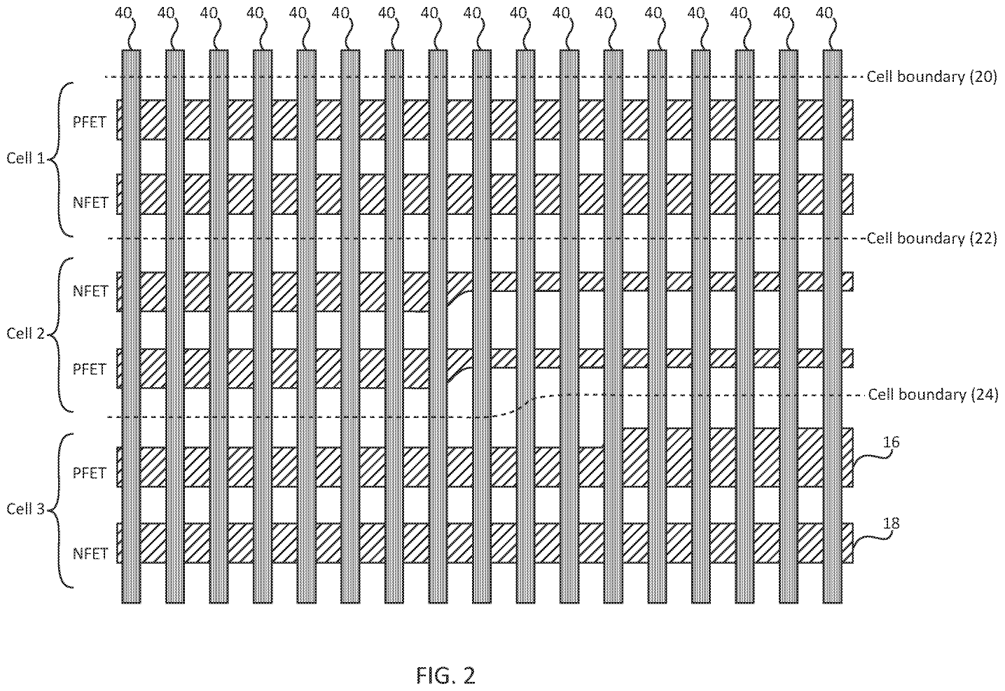

FIG. 2 is a cross-sectional view of the semiconductor structure of FIG. 1 where dummy gates are formed, in accordance with an embodiment of the present invention.

In various example embodiments, dummy gates 40 are formed perpendicular to the active regions of the NFETs and PFETs of the Cells 1, 2, and 3. The dummy gates 40 extend perpendicular across of the cells and all the cell boundaries 20, 22, 24.

The dummy gates 40 can be composed of any type of sacrificial material.

In various embodiments, the dummy gates 40 can include a thin layer of dummy gate oxide and dummy poly-Si or a-Si over the dummy gate oxide, with gate hardmask made of dielectrics such as SiN or SiO2 or combination of SiN and SiO2 over the dummy poly-Si or a-Si.

In some embodiments, the dummy gate materials and various dielectrics can be deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

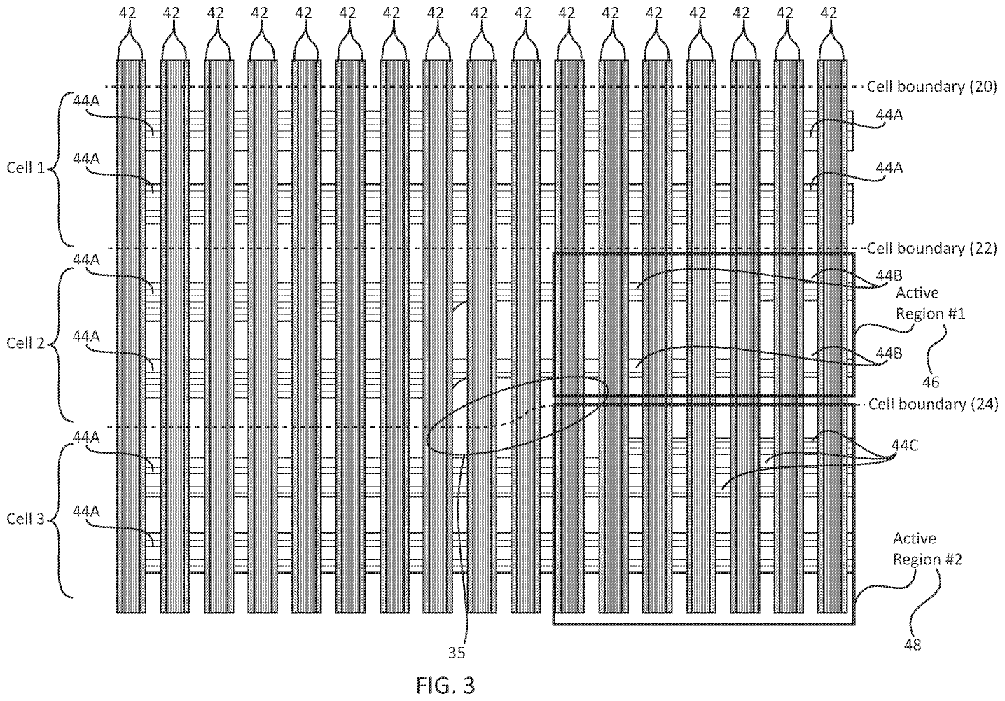

FIG. 3 is a cross-sectional view of the semiconductor structure of FIG. 2 where spacers and source/drain (S/D) epi regions are formed adjacent the dummy gates, in accordance with an embodiment of the present invention.

In various example embodiments, spacers 42 and source/drain (S/D) epi regions 44 are formed adjacent the dummy gates 40. The spacers 42 are disposed on opposed ends of the dummy gates 40. The S/D epi regions 44 are formed between the spacers 42. There are several different types of S/D epi regions.

The S/D epi regions between the PFET 12P and the NFET 12N of Cell 1 are designated as S/D epi regions 44A. Since the S/D epi regions 44A are formed within Cell 1, which is bound by straight lines, all the S/D epi regions 44A are the same or have the same shape.

The S/D epi regions between the NFET 14N and the PFET 14P of Cell 2 are designated as S/D epi regions 44A and S/D epi regions 44B. Cell 2 is bound by a straight line 22 and a curved cell boundary 24. This results in smaller S/D epi regions 44B on the right-hand side of Cell 2 where the curvature 35 shrinks Cell 2 on the right-hand side.

The S/D epi regions between the PFET 16 and the NFET 18 of Cell 3 are designated as S/D epi regions 44A and S/D epi regions 44C. Cell 3 is bound by the curved cell boundary 24 at a top portion thereof. This results in larger S/D epi regions 44C on the right-hand side of Cell 3 where the curvature 35 enlarges Cell 3 on the right-hand side. The curvature 35 of the cell boundary 24 thus results in the modification of the S/D epi regions 44 disposed between the dummy gates 40.

Additionally area 46 can be referred to as a reduced active region and area 48 can be referred to as a widened active region. The reduced active region 46 is separated from the widened active region 48 by the curvature 35 of the cell boundary 24.

The spacers 42 can include any of one or more of SiN, SiBN, SiCN and/or SiBCN films.

S/D epi regions 44 can be of the same or different materials for pFET and nFET devices, and can be either in-situ doped with appropriate polarity dopants (B for pFET and P for nFET devices) or doped by ion implantation.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

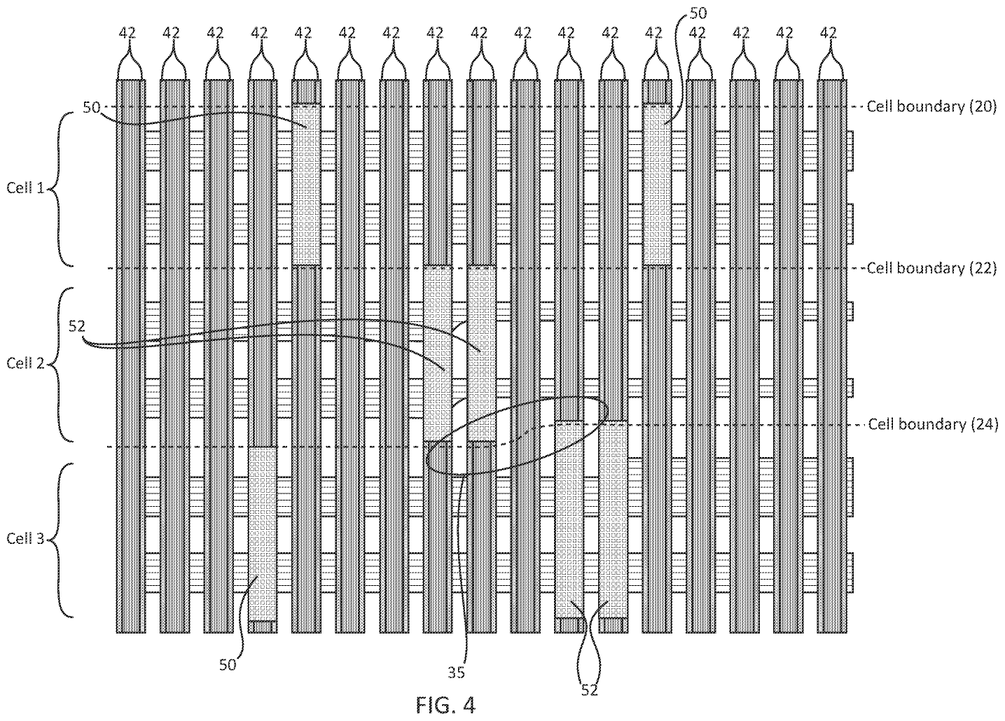

FIG. 4 is a cross-sectional view of the semiconductor structure of FIG. 3 where single diffusion breaks and double diffusion breaks are illustrated, in accordance with an embodiment of the present invention.

In various example embodiments, single diffusion breaks and double diffusion breaks are illustrated. Cell 1 illustrates a single diffusion break 50, Cell 2 illustrates a double diffusion break 52, and Cell 3 illustrates a single diffusion break 50 (left-hand side) and a double diffusion break 52 (right-hand side), adjacent to the curvature 35 of the cell boundary 24.

Design systems are commonly used to design integrated circuits (ICs) and, in particular, to design front end of line (FEOL) components. As advances occur, smaller widths for wires and vias are provided. Additional design constrains imposed by smaller wire and via widths, e.g., requirements for unidirectional wiring at any metal layer, may preclude the use of non-linear wiring in a metal layer. The intended circuit structure must comply with these design rules before manufacture. Design rule spacing constraints can limit a variety of attributes, e.g., the maximum separation distance between adjacent gates in a cell array. Such constraints can affect the ability to form functional elements which connect gates and/or other structures together, e.g., two or more vias connecting to nearby positions of a single device layer.

To separate the various functional components of a product from each other, it may be necessary to form one or more isolation regions between two or more conductive or semiconductor regions of the product. Some isolation regions may be positioned over different types of components, e.g., over other insulating regions or over functional components. To accommodate the different locations and types of isolation regions, it is generally necessary to fabricate a different mask for each isolation structure and include various structural features, intermediate components, etc., to protect previously-formed structures or other regions from being processed to yield additional isolation regions. The structural differences at each location where an isolation region is needed may prevent the use of a single mask to form multiple types of isolation regions in the same structure.

A design rule for a product may include two locations L1, L2, where gate structures must be removed for replacement with an electrically insulator material, e.g., a diffusion break for electrically separating two portions of the same fin, or an end isolation region (also known as a “gate cut region”) for laterally separating two functional gates from each other. Portions of gate structure in the first location may represent a dummy gate positioned over the targeted location of a single diffusion break. Forming a single diffusion break in first location will isolate active regions on opposite side of the single diffusion break from each other. Portions of gate structure in second location may represent an eventual end isolation region or “gate cut region,” where underlying materials will be removed and replaced with insulator materials. The exemplary embodiments of the present invention introduce both single diffusion breaks 50 and double diffusion breaks 52 for electrically separating portions of the circuit rows having the NFETs and PFETs.

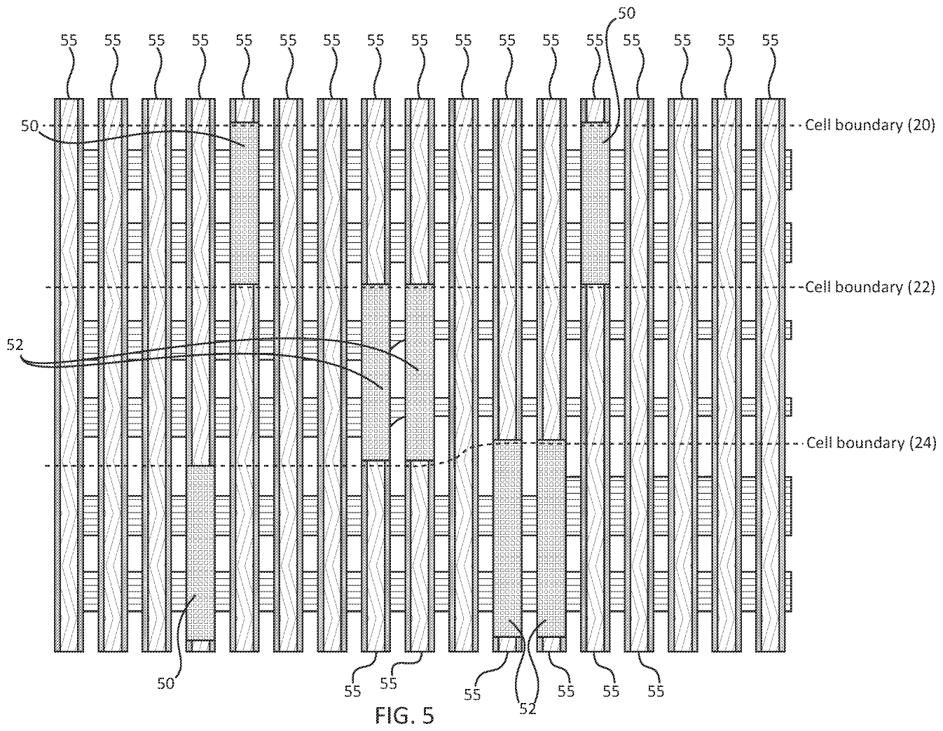

FIG. 5 is a cross-sectional view of the semiconductor structure of FIG. 4 where the dummy gates are removed and replaced with replacement metal gates (RMG), in accordance with an embodiment of the present invention.

In various example embodiments, the dummy gates 40 are removed and replaced with replacement metal gates (RMG) 55. Additionally area 46 can be referred to as a reduced active region and area 48 can be referred to as a widened active region. The reduced active region 46 is separated from the widened active region 48 by the curvature 35 of the cell boundary 24, as well as the curved gate cut 64.

The HKMG material of the replacement metal gates 55 can be deposited by any suitable techniques, such as ALD, CVD, metal-organic CVD (MOCVD), physical vapor deposition (PVD), thermal oxidation, combinations thereof, or other suitable techniques. The gate dielectric material of the replacement metal gates 55 can include, e.g., HfO₂, LaO, AlO, ZrO, TiO, Ta₂O₅, Y₂O₃, SrTiO₃(STO), BaTiO₃(BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. The HKMG of the RMG gate 55 further comprises work function metals, such as TiN, TiAl, TiC, TiAIC, etc., and conductive metal fills, such as W, Al, Ru, etc.

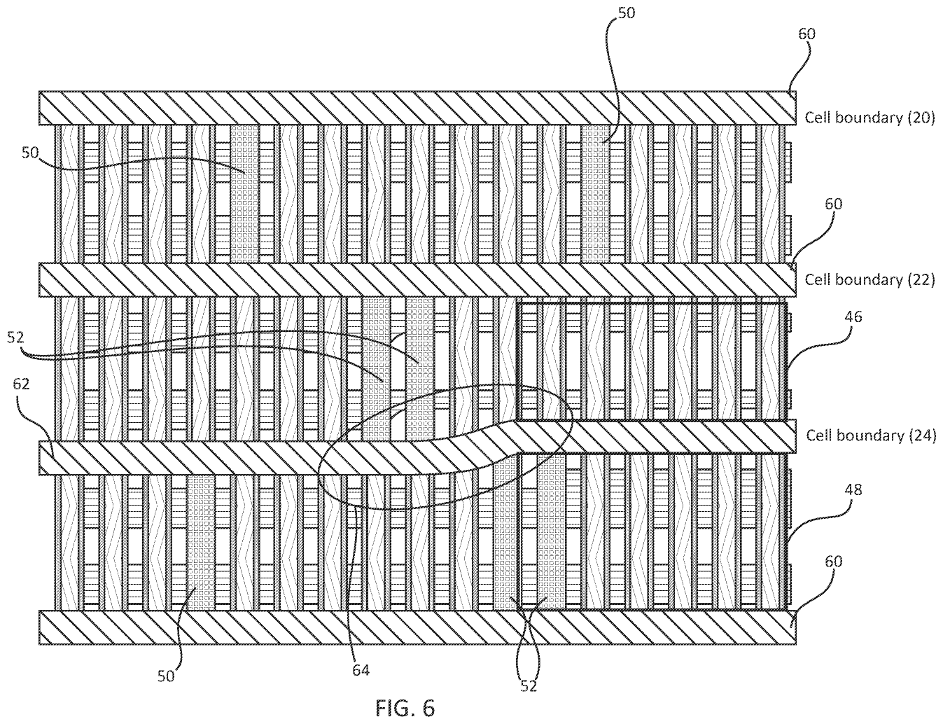

FIG. 6 is a cross-sectional view of the semiconductor structure of FIG. 5 where gate cuts takes place, where at least one gate cut is curved, in accordance with an embodiment of the present invention.

In various example embodiments, gate cuts 60 takes place at the cell boundaries, where at least one gate cut is curved, that is, curved gate cut 62 with curved gate cut 64. The gate cuts 60, 62 follow the cell boundaries.

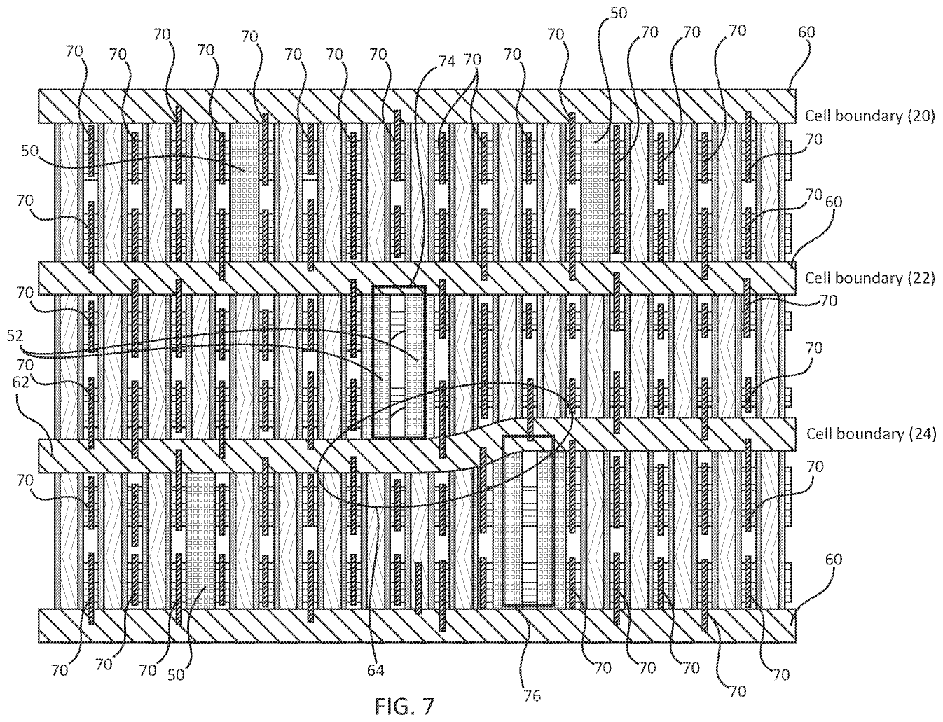

FIG. 7 is a cross-sectional view of the semiconductor structure of FIG. 6 where contacts are formed to the S/D epi regions, in accordance with an embodiment of the present invention.

In various example embodiments, contacts 70 are formed to the S/D epi regions 44. Contacts 70 can be referred to as CA contacts. CA contacts can also be referred to as S/D contacts. It is noted that CA contacts are not necessary between the dummy gates of the double diffusion break illustrated on regions 74 and 76.

Non-limiting examples of suitable conductive materials for the CA contacts 70 include a silicide liner such as Ti, Ni, NiPt, etc., an adhesion metal liner, such as TiN, TaN, and conductive metal fill, such as Al, W, Co, Ru, etc. The conductive material can further include dopants that are incorporated during or after deposition. The conductive metal can be deposited by a suitable deposition process, for example, CVD, PECVD, PVD, plating, thermal or e-beam evaporation, and sputtering.

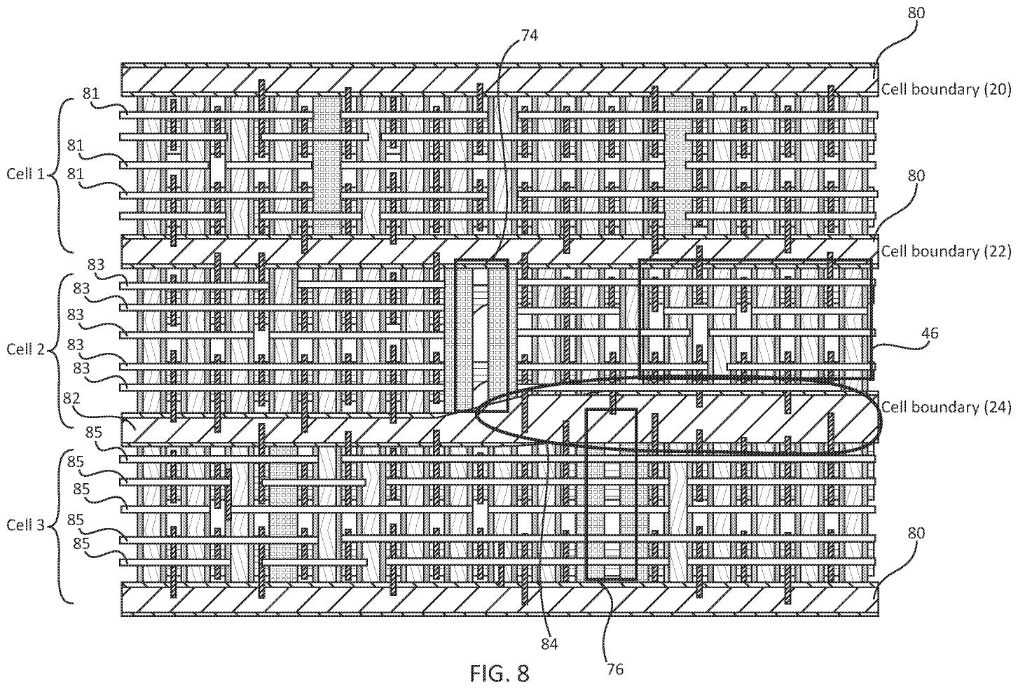

FIG. 8 is a cross-sectional view of the semiconductor structure of FIG. 7 where M1 metallization lines are formed and are mostly straight, in accordance with an embodiment of the present invention.

In various example embodiments, M1 metallization lines 80, 82 are formed and are mostly straight. Lines 81 are formed within Cell 1, lines 83 are formed within Cell 2, and lines 85 are formed within Cell 3. Region 84, where the curved gate cut 64 of the gate cut 62 is positioned is a thick region. Region 84 is thicker than M1 lines 80.

M1 metallization lines 80, 82 can be any conductive material such as Cu, or Co or Ru.

The metallization layer M1 may be formed by depositing a metal layer and patterning the metal layer to form conductive lines. An insulating layer may then be formed over the patterned metal layer. Alternatively, the metallization layer M1 may be formed using a damascene process. Metal lines 80 and 82 can be power rails, and metal lines 81, 83, and 85 can be signal wires.

Additionally area 46 can be referred to as a reduced active region and area 48 can be referred to as a widened active region. The reduced active region 46 is separated from the widened active region 48 by the curvature 35 of the cell boundary 24, as well as the curved gate cut 64 of the gate cut 62 in region 84. Thus, the at least one curved gate cut region 84 separates a reduced active area from a widened active area such that the reduced active area is defined above the curved cell boundary 82 and the widened active area is defined below the curved cell boundary 82.

Each of the plurality of cells includes a plurality of n-type field-effect transistors (NFETs) and a plurality of p-type field-effect-transistors (PFETs). A portion of the plurality of PFETs above the at least one curved gate cut region 84 are smaller is size than a portion of the plurality of PFETs below the at least one curved gate cut region 84.

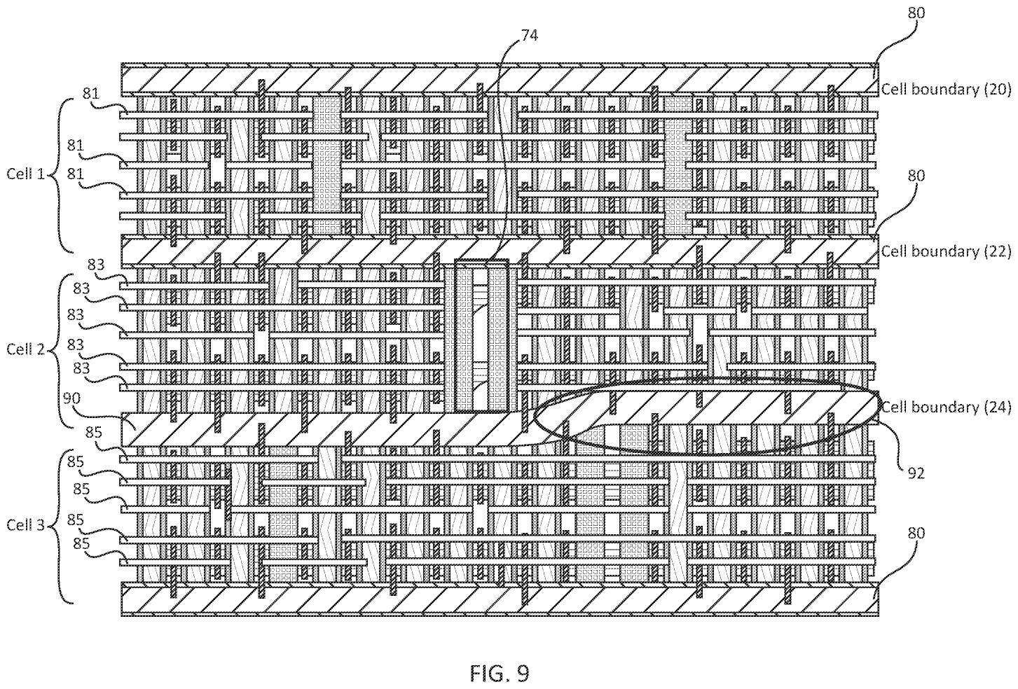

FIG. 9 is a cross-sectional view of the semiconductor structure where M1 metallization lines are formed and some M1 lines are curved with the curved gate cut, in accordance with another embodiment of the present invention.

In various example embodiments, M1 metallization lines 80 are formed and some M1 lines 90 are curved (curve 92) with the gate cut. Similarly, the reduced active region 46 is separated from the widened active region 48 by the curvature 35 of the cell boundary 24, as well as the curved gate cut 64 of the gate cut 62 in region 92. Line 90 in FIG. 9 is not as thick as line 82 in FIG. 8. Curve 92 in FIG. 9 is further emphasized or further defined than the curve in region 84 of FIG. 8.

In conclusion, the exemplary embodiments of the present invention present a method and structure of forming a curved gate cut at a cell boundary and a locally larger active region next to a locally small active region to improve circuit performance. The circuit includes at least a curved gate region over a curved cell boundary, where at least a reduced active region and a widened active region are separated by the curved gate cut region.

Devices formed in accordance with embodiments of the present disclosure are useful in various industrial applications, e.g., microprocessors, smart phones, mobile phones, cellular handsets, set-top boxes, DVD recorders and players, automotive navigation, printers and peripherals, networking and telecom equipment, gaming systems, and digital cameras. The present disclosure therefore has industrial applicability in any of various types of highly integrated semiconductor devices.

Regarding FIGS. 1-9, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Any etching can include a dry etching process such as, for example, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process that uses a chlorine-based chemistry. Other dry etchant gasses can include Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIG. 1t will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for a flexible cell boundary with a curved gate cut region (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A circuit comprising:
a plurality of cells separated by a plurality of cell boundaries; and
at least one curved gate cut region disposed over a curved cell boundary of the plurality of cell boundaries.

2. The circuit of claim 1, wherein the at least one curved gate cut region separates a reduced active area from a widened active area.

3. The circuit of claim 2, wherein the reduced active area is defined above the curved cell boundary and the widened active area is defined below the curved cell boundary.

4. The circuit of claim 2, wherein the widened active area includes a double diffusion break.

5. The circuit of claim 1, wherein the at least one curved gate cut region is defined between two straight cell boundaries of the plurality of cell boundaries.

6. The circuit of claim 1, wherein the at least one curved gate cut region includes a first double diffusion break on one end thereof and a second double diffusion break on another end thereof.

7. The circuit of claim 1, wherein each cell of the plurality of cells includes a plurality of n-type field-effect transistors (NFETs) and a plurality of p-type field-effect-transistors (PFETs).

8. The circuit of claim 7, wherein a portion of the plurality of PFETs above the at least one curved gate cut region are smaller is size than a portion of the plurality of PFETs below the at least one curved gate cut region.

9. The circuit of claim 7, wherein tapered edges of the NFETs and PFETs face the curved cell boundary.

10. A semiconductor device comprising:
a first circuit row including a first circuit portion having a first width and a second circuit portion having a second width, the first and second circuit portions being adjacent to each other; and
a second circuit row including a third circuit portion having a third width and a fourth circuit portion having a fourth width, the third and fourth circuit portions being adjacent to each other;
wherein the first width is larger than the second width and the fourth width is larger than the third width.

11. The semiconductor device of claim 10, wherein the first circuit row is separated from the second circuit row by a curved cell boundary.

12. The semiconductor device of claim 11, wherein at least one curved gate cut region is disposed over the curved cell boundary.

13. The semiconductor device of claim 12, wherein the second circuit portion is a reduced active area and the fourth circuit portion is a widened active area.

14. The semiconductor device of claim 13, wherein the widened active area includes a double diffusion break.

15. The semiconductor device of claim 13, wherein the at least one curved gate cut region includes a first double diffusion break on one end thereof and a second double diffusion break on another end thereof.

16. The semiconductor device of claim 11, wherein tapered edges of the circuits in the first and second circuit rows face the curved cell boundary.

17. A method comprising:
separating a plurality of cells by a plurality of cell boundaries; and
constructing at least one curved gate cut region over a curved cell boundary of the plurality of cell boundaries.

18. The method of claim 17, wherein the at least one curved gate cut region separates a reduced active area from a widened active area.

19. The method of claim 18, wherein the reduced active area is defined above the curved cell boundary and the widened active area is defined below the curved cell boundary.

20. The method of claim 17, wherein each cell of the plurality of cells includes a plurality of n-type field-effect transistors (NFETs) and a plurality of p-type field-effect-transistors (PFETs) such that tapered edges of the NFETs and PFETs face the curved cell boundary.
